(19) United States
(12) Patent Application Publication
(10) Pub. No.: US 2024/0353204 A1
(43) Pub. Date: Oct. 24, 2024

(54) ARTICLE, AND STRUCTURAL BODY

(71) Applicant: CANON KABUSHIKI KAISHA, Tokyo (JP)

(72) Inventors: YOSHINORI KOTANI, Kanagawa (JP); HIROSHI SAITO, Kanagawa (JP)

(21) Appl. No.: 18/635,886

(22) Filed: Apr. 15, 2024

(30) Foreign Application Priority Data
Apr. 18, 2023 (JP) 2023-068096
Jan. 16, 2024 (JP) 2024-004627

(51) Int. Cl. F41H 3/00; H05K 9/00

(52) U.S. Cl. CPC F41H 3/00; H05K 9/0094

(57) ABSTRACT

An article includes a first region, and a second region disposed from the first region within a distance equal to or less than a width of the first region. An emissivity of infrared light in a first wavelength in the first region and the second region is equal to or less than 90%, and a reflectance of visible light in a second wavelength in the first region and the second region is equal to or less than 10%. A difference between an average emissivity (%) of infrared light in a wavelength equal to or greater than 8 μm and equal to or less than 13 μm in the first region, and an average emissivity (%) of infrared light in a wavelength equal to or greater than 8 μm and equal to or less than 13 μm in the second region is equal to or greater than 5%.

### BACKGROUND

### Field of the Disclosure

The present disclosure relates to an article, and a structural body.

### Description of the Related Art

There has been conventionally known a technique of controlling the reflection of visible light with a method of applying color similar to that of the background, attaching an object, such as a plant, that is similar to the background, or the like, as a technique of making a vehicle, a facility, a human, and the like less discoverable. Nevertheless, a large amount of infrared light is emitted outward from an object releasing heat, so that the technique of controlling the reflection of visible light is less effective for a radar that detects infrared light.

In view of the foregoing, Japanese Patent Application Laid-Open No. H06-273095 discusses a plate-like or foil-like object that has a low emissivity of infrared light, and has a property adjusted to absorb visible light in most wavelengths, or reflect only light in a specific wavelength at a desired reflectance.

The configuration discussed in Japanese Patent Application Laid-Open No. H06-273095 leaves room of examination for the emission of infrared light.

### SUMMARY

According to an aspect of the present disclosure, an article includes a first region, and a second region disposed from the first region within a distance equal to or less than a width of the first region. An emissivity of infrared light in a first wavelength in the first region and the second region is equal to or less than 90%, and a reflectance of visible light in a second wavelength in the first region and the second region is equal to or less than 10%. A difference between an average emissivity (%) of infrared light in a wavelength equal to or greater than 8 μm and equal to or less than 13 μm in the first region, and an average emissivity (%) of infrared light in a wavelength equal to or greater than 8 μm and equal to or less than 13 μm in the second region is equal to or greater than 5%.

Further features of the present disclosure will become apparent from the following description of embodiments with reference to the attached drawings.

### BRIEF DESCRIPTION OF THE DRAWINGS

FIG. 1 is a schematic diagram illustrating an article according to an embodiment of the present disclosure in a planar view.

FIG. 2 is a sectional view of a region in the article.

FIG. 3 is a sectional view of a region in a member.

FIGS. 4A to 4D are diagrams illustrating a manufacturing method of an article.

FIG. 5 illustrates a result of an emissivity spectrum measurement of infrared light in regions.

FIG. 6 illustrates a result of a reflectance spectrum measurement of visible light in regions.

FIG. 7A illustrates an image obtained by observing an article prepared in an example, in an infrared region, and FIG. 7B illustrates an image obtained by observing an article prepared in an example, in a visible region.

FIG. 8 is a sectional view of a region in a member.

### DESCRIPTION OF THE EMBODIMENTS

Hereinafter, an embodiment of the present disclosure will be described with reference to the drawings. The embodiment to be described below is one embodiment of the disclosure, and the disclosure is not limited to this. Common components will be described with reference to a plurality of drawings, and the description of components assigned the same reference numerals will be appropriately omitted. Different components with the same name can be distinguished from each other by adding “N-th” like a first component and a second component.

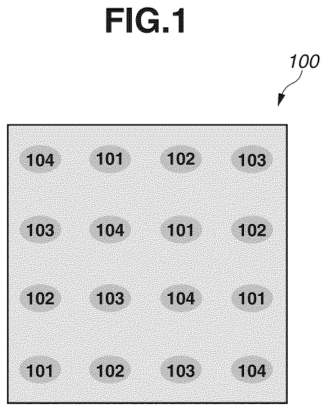

A first embodiment of the present disclosure will be described below. Hereinafter, an article 100 according to the present embodiment will be described with reference to the accompanying drawings. FIG. 1 is a schematic diagram illustrating the article 100 according to the present embodiment in a planar view. The article 100 according to the present embodiment is configured to be less likely to emit infrared light. For example, an emissivity (hereinafter, a high emissivity will be sometimes referred to as a high heat shield property) of infrared light in a certain wavelength (first wavelength) in the entire article 100 is set to 90% or less, so that the emission of infrared light is controlled. If the emissivity of infrared light exceeds 90%, infrared light is emitted too much, an effect may fail to be produced. The article 100 is applicable to any object that emits infrared light, and is configured to control the emission of infrared light as long as an emissivity of infrared light falls within the above-described range of an emissivity of infrared light. The certain wavelength in the emissivity of infrared light in the certain wavelength is preferably 6 μm or more, and is more preferably a wavelength equal to or greater than 8 μm and equal to or less than 13 μm.

The article 100 includes a plurality of regions (regions 101, 102, 103, and 104), and an emissivity of infrared light varies for each region. For example, it is preferable that a difference in average emissivity (%) of infrared light in a wavelength equal to or greater than 8 μm and equal to or less than 13 μm, between the region 101 and the region 102 neighboring the region 101 is equal to or greater than 5%. This enables the entire article 100 to be less visible by infrared light, and creates an infrared camouflage state as the entire article 100, thus exhibiting an excellent thermal camouflage effect. Furthermore, the difference equal to or greater than 10% produces a larger effect. The difference is preferably equal to or less than 50%, and if the difference is equal to or less than 30%, it is possible to create an infrared camouflage state as the entire article 100, exhibiting an excellent thermal camouflage effect. The average emissivity of infrared light in the wavelength equal to or greater than 8 μm and equal to or less than 13 μm is an average emissivity obtainable when infrared light in each of the wavelengths of 8 μm, 9 μm, 10 μm, 11 μm, 12 μm, and 13 μm is emitted to the article 100.

Among the regions, regions having the same infrared light emissivity are preferably provided in a direction different from a longitudinal direction and a traverse direction of the article 100. For example, in the case of FIG. 1, the direction is a diagonal direction in the article 100. Since the arrangement of the regions in this manner enables the article 100 to be less visible, it is preferable that the regions are alternately arranged. In FIG. 1, regions other than the plurality of regions 101 to 104 are present between the regions, but the regions 101 to 104 may be provided in contact.

As the shape of the regions 101 to 104, a circle, an ellipse, a polygon such as a quadrangle, a rhomboid, a star shape, a wave shape, and the like are applicable. The shapes of the regions may be the same, or all the regions may have different shapes. An area of the regions 101 to 104 is preferably equal to or greater than 25 cm² and equal to or less than 10000 cm². In a case where the shape of the regions 101 to 104 is a quadrangle, a longitudinal length and a traverse length are preferably equal to or greater than 5 cm and equal to or less than 100 cm.

The article 100 according to the present embodiment preferably has not only a configuration of being less visible by infrared light, but also a configuration of being less visible by visible light. For example, a reflectance (hereinafter, a low reflectance will be sometimes referred to as a high light absorption property) of visible light in a certain wavelength (second wavelength) in the entire article 100 is set to 10% or less, so that black-based coloration less visible by visible light is provided. Furthermore, as in an infrared light region, reflectances of neighboring regions are preferably different also in a visible light region. For example, a difference in reflectance of visible light between the regions 101 and 102 is preferably equal to or less than 10%. Furthermore, a difference in average reflectance of visible light in a wavelength equal to or greater than 450 nm and equal to or less than 650 nm is preferably equal to or less than 10%. This enables the entire article 100 to be less visible by visible light, so that a visible camouflage state as the entire article 100 is provided. Furthermore, if the difference is equal to or less than 5% or equal to or less than 3%, it is possible to create black-based coloration as the entire article 100, and exhibit a larger effect. The average reflectance of visible light in the wavelength equal to or greater than 450 nm and equal to or less than 650 nm is an average reflectance when visible light in each of the wavelengths of 450 nm, 500 nm, 550 nm, 600 nm, and 650 nm is emitted to the article 100. As the certain wavelength in the reflectance of visible light in the certain wavelength (second wavelength), a wavelength of visible light is preferably equal to or greater than 400 nm and equal to or less than 750 nm, and is more preferably equal to or greater than 450 nm and equal to or less than 650 nm.

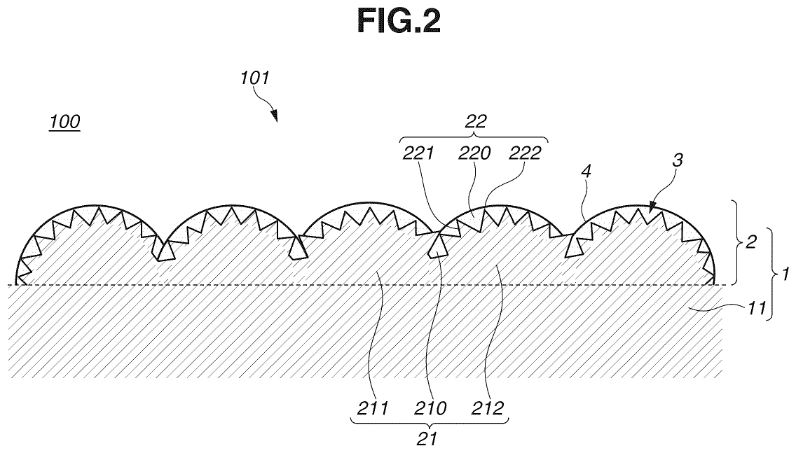

Next, configurations of the regions 101 to 104 will be described with reference to FIG. 2. FIG. 2 is a sectional view of the region 101. The description will now be provided using the region 101 as an example, but the regions 102 to 104 can also employ a similar configuration.

The article 100 includes a metal layer 1 including an irregularity structure 2 on one principal surface. The metal layer 1 further includes a base portion 11 forming the surface of the metal layer 1. A metal with high electric conductivity is preferable as the material of the metal layer 1. Examples of metal with high electric conductivity include silver, copper, gold, aluminum, magnesium, tungsten, cobalt, zinc, nickel, chrome, and the like. Among them, nickel, zinc, and chrome are preferable, and nickel is especially preferable. The irregularity structure 2 provided on the surface of the metal layer 1 is preferably made of metal with high electric conductivity, and is more preferably made of the same metal as that of the base portion 11 of the metal layer 1.

The base portion 11 is a portion in which the metal layer 1 is continuous over the entire region 101, and the irregularity structure 2 is a portion in which the metal layer 1 is discontinuous over the entire region 101. In FIG. 2, a boundary between the base portion 11 and the irregularity structure 2 is indicated by a broken line.

The irregularity structure 2 includes a first irregularity structure 21 and a second irregularity structure 22. An object having the irregularity structure 2 is an irregularity structural object. The irregularity structure 2 is part or all of the irregularity structure, so that the irregularity structure 2 can also be referred to as an irregularity structural object.

The first irregularity structure 21 includes a plurality of protruding portions (e.g., protruding portions 211 and 212). The first irregularity structure 21 includes a plurality of recess portions (e.g., a recess portion 210 between the protruding portions 211 and 212). The presence of the first irregularity structure 21 enables the article 100 to exhibit a higher emissivity of infrared light, producing a heat shield effect. The protruding portions 211 and 212 of the first irregularity structure 21 constitute part of the metal layer 1, and the recess portion 210 of the first irregularity structure 21 is a space where the metal layer 1 may be absent and a substance other than the metal layer 1 may be present.

The second irregularity structure 22 includes a plurality of protruding portions (e.g., protruding portions 221 and 222). The second irregularity structure 22 includes a plurality of recess portions (e.g., a recess portion 220 between the protruding portions 221 and 222). The presence of the second irregularity structure 22 enables the article 100 to exhibit a lower reflectance of visible light, producing a light absorption effect. The protruding portions 221 and 222 of the second irregularity structure 22 constitute part of the metal layer 1, and the recess portion 220 of the first irregularity structure 21 is a space where the metal layer 1 may be absent and a substance other than the metal layer 1 may be present.

The second irregularity structure 22 is preferably formed on the top surface of the first irregularity structure 21. This configuration increases the light absorption effect of the article 100. In other words, the second irregularity structure 22 is disposed on the top surface of each of a plurality of protruding portions (e.g., the protruding portions 211 and 212) included in the first irregularity structure 21. Main components of metal materials of the first irregularity structure 21 and the second irregularity structure 22 are preferably the same. The base portion 11, the first irregularity structure 21, and the second irregularity structure 22 are formed with a common metal material (i.e., single-layered metal layer 1), so that excellent light absorption property and heat shield property are achieved as compared with a case where these are formed with different metal materials (i.e., multilayered metal layer).

The metal layer 1 which is an irregularity structural object in the article 100 includes the base portion 11 made of a metal material having the same main component as that of the first irregularity structure 21 and the second irregularity structure 22, under the first irregularity structure 21. The base portion 11 continuously extends under a plurality of protruding portions (e.g., the protruding portions 211 and 212) included in the first irregularity structure 21. In contrast to this, in the irregularity structure 2, the metal layer 1 is discontinuous due to a recess portion (e.g., the recess portion 210) of the first irregularity structure 21 or the recess portion 220 of the second irregularity structure 22. In other words, protruding portions (e.g., the protruding portions 211 and 212) of the first irregularity structure 21 are discontinuous due to the recess portion 210. Protruding portions (e.g., the protruding portions 221 and 222) of the second irregularity structure 22 are discontinuous due to the recess portion 220. Herein, the main component of the material refers to a component having the highest molar content ratio among the constituent elements when a material includes a plurality of constituent elements.

An average roughness Ra of the first irregularity structure 21 is preferably equal to or greater than 0.1 μm and equal to or less than 5 μm, and an average roughness Ra of the second irregularity structure 22 is preferably equal to or greater than 1 nm and equal to or less than 50 nm. With this configuration, the above-described effects produced by the presence of the first irregularity structure 21 and the second irregularity structure 22 become more prominent. In this example, the first irregularity structure 21 and the second irregularity structure 22 in the region 101 have been described. Similar irregularity structures 2 are preferably provided also in the regions 102 to 104.

An arithmetic average roughness Ra of at least one of the first irregularity structure 21 and the second irregularity structure 22 is varied, so that it is possible to change an emissivity of infrared light or a reflectance of visible light between the regions 101 to 104.

Here, an average roughness of the irregularity structure 2 or an average roughness of the irregularity structure 2 to which a transparent metal oxide to be described below adheres means an arithmetic average roughness defined in “Definition and Designation of Surface Roughness” of JIS-B-0601. When only a reference length is extracted, from the roughness curve, in a direction of its average line, and when a direction of an average line of an extracted portion is set to an X-axis, a direction of a longitudinal magnification is set to Y-axis, and a roughness curve is represented by y=f(x), the average roughness Ra is obtained by the following equation (1).

$$Ra = \frac{1}{L} {\int }_{0}^{L} \vert f ( x ) \vert dx \qquad ( 1 )$$

In Equation (1), Ra denotes an average roughness (nm), L denotes a reference length, and F (X, Y) denotes a height at a measurement point (X, Y) of which an X coordinate is X and a Y coordinate is Y.

Furthermore, in the article 100 according to the present embodiment, a maximum height Rz of the first irregularity structure 21 on the surface of the metal layer 1 is preferably equal to or greater than 1 μm and equal to or less than 10 μm, and a maximum height Rz of the second irregularity structure 22 is preferably equal to or greater than 100 nm and equal to or less than 800 nm. With this configuration, the above-described effects produced by the presence of the first irregularity structure 21 and the second irregularity structure 22 become more prominent.

Here, the maximum height of the irregularity structure 2 or the maximum height of the irregularity structure 2 to which a transparent metal oxide to be described below adheres means a maximum height defined in “Definition and Designation of Surface Roughness” of JIS-B-0601. The maximum height is a maximum height determined by extracting only a reference length from a roughness curve in a direction of its average line, and measuring an interval between a summit line and a valley floor line of an extracted portion in a direction of a longitudinal magnification of the roughness curve. This valley floor line can correspond to the boundary between the base portion 11 and the irregularity structure 2 that is indicated by the broken line in FIG. 2. The average roughness Ra and the maximum height Rz of the irregularity structure 2 are obtainable by observing a section of the article 100 according to the present embodiment using a scanning electron microscope or the like.

The article 100 according to the present embodiment includes metal oxide layers 3 and 4 provided on one principal surface of the metal layer 1. The metal oxide layers 3 and 4 may be omitted.

A transparent metal oxide layer 3 preferably adheres to the surface of the irregularity structure 2. In other words, the article 100 preferably includes the transparent metal oxide layer 3 on the surface of the irregularity structural object serving as the metal layer 1. The metal oxide layer 3 is preferably disposed over the entire surface of the irregularity structural object, but the metal oxide layer 3 is only required to be disposed on at least the protruding portions (e.g., the protruding portions 221 and 222). A metal constituent of the metal oxide layer 3 adhering to the surface of the irregularity structure 2 is preferably different from a metal constituent of the metal layer 1. In other words, if the main material of the metal layer 1 is nickel, for example, the metal oxide layer 3 adhering to the surface of the irregularity structure 2 is mainly made of an oxide of metal other than nickel. Accordingly, the metal oxide layer 3 adhering to the surface of the irregularity structure 2 is distinguishable from a metal oxide that is formed by natural oxidation of the metal layer 1 or the like and that has the same metal constituent as a metal constituent of the metal layer 1.

In this specification, the metal oxide layers 3 and 4 will be sometimes referred to as a metal oxide. The metal oxide layer 3 is disposed between a plurality of protruding portions (e.g., the protruding portions 221 and 222) included in the second irregularity structure 22. In other words, it is preferable that the metal oxide layer 3 buries a recess portion of the second irregularity structure 22 (e.g., the recess portion 220 between the protruding portions 221 and 222), and is formed into a film shape.

The article 100 of the present disclosure may further include a transparent metal oxide layer 4 covering the surface of the metal oxide layer 3 that is not in contact with the irregularity structure 2. It is preferable that the metal oxide layer 4 covers the irregularity structure 2 and the metal oxide layer 3 is disposed between the metal oxide layer 4 and the metal layer 1.

Although the material of the metal oxide layer 3 is not specifically limited, the metal oxide layer 3 preferably contains aluminum oxide as a main component, and more preferably includes a plate-like crystal (hereinafter, will be referred to as a plate crystal) containing aluminum oxide as a main component. The plate crystal containing aluminum oxide as a main component is formed by a crystal containing oxide or hydroxide of aluminum, or a hydrate of these as a main component, and an especially-preferable crystal is boehmite. Here, the plate crystal containing aluminum oxide as a main component may be a plate crystal containing only aluminum oxide, or may be a plate crystal containing a slight amount of zirconium, silicon, titanium, zinc, or the like in a plate crystal of aluminum oxide.

In this manner, the article 100 includes the metal oxide layer 3, so that the irregularity structure 2 is protected. In a case where the metal oxide layer 3 is a plate-like structure of a plate crystal containing aluminum oxide as a main component, it is preferable that the plate crystal containing aluminum oxide as a main component is arranged in a vertical direction relative to a surface direction of the metal layer 1, and a spatial occupancy rate thereof continuously changes.

While the material of the metal oxide layer 4 is not specifically limited, the metal oxide layer 4 preferably contains amorphous gel of aluminum oxide. While the metal oxide layer 4 increases the hardness of the surface of the article 100 according to the present embodiment, the metal oxide layer 4 decreases a light absorption property. It is therefore desirable that the thickness of the metal oxide layer 4 is appropriately determined in such a manner as to satisfy required hardness and light absorption property.

An aluminum element, a silicon element, and the like in the irregularity structure 2, the metal oxide layer 3, and the metal oxide layer 4 are detectable by the measurement of a surface using a scanning electron microscope (SEM) or a transmission electron microscope (TEM). These are also detectable by the measurement through energy dispersive X-ray spectroscopy (EDX) or X-ray photoelectron spectroscopy (XPS) during cross-section observation. Similarly, metal elements of silver, copper, gold, aluminum, magnesium, tungsten, cobalt, zinc, nickel, chrome, and the like in the metal layer 1 are also detectable by the measurement of a surface using an SEM or a TEM. Similarly, a silicon element, a fluorine element and the like in a covering layer are also detectable by the measurement of a surface using an SEM or a TEM. These are also detectable by the measurement through the EDX or the XPS during cross-section observation. In a case where the irregularity structure 2, the metal oxide layer 3, or the metal oxide layer 4 is disposed, a rate of a metal oxide of an aluminum element or the like becomes relatively lower from the surface (the metal oxide layer 4) toward the inside (the metal layer 1) in the vertical direction relative to the surface direction of the metal layer 1. In contrast, a rate of metal elements included in the metal layer 1 and the irregularity structure 2 becomes relatively higher from the surface (the metal oxide layer 4) toward the inside (the metal layer 1), and only the metal elements are finally detected.

The article 100 of a present embodiment includes a covering layer 40 that is disposed on the metal oxide layers 3 and 4, and includes a material different from that of the metal oxide layers 3 and 4. The metal oxide layer 4 may be omitted. The covering layer 40 that is in contact with the metal oxide layers 3 and 4 and includes a material different from those of the metal oxide layers 3 and 4, preferably includes Si and O as an inorganic material, more preferably includes siloxane, and further preferably includes silsesquioxane. In addition to inclusion of the covering layer 40 made of the above-described inorganic material, the article 100 according to an embodiment of the present embodiment preferably further includes the covering layer 40 made of an organic material. As the organic material, the covering layer 40 preferably includes fluorine resin or acrylic resin. As described above, the material of the metal oxide layers 3 and 4 is aluminum oxide, for example. The covering layer 40 including a material different from that of the metal oxide layers 3 and 4 means that materials are different in that, while the metal oxide layers 3 and 4 mainly include Al (aluminum), for example, the covering layer 40 mainly includes silicon (Si) as an inorganic material and mainly includes carbon (C) as an organic material. At this time, this does not mean that the covering layer 40 contains no AI at all. When the main material of the metal oxide layers 3 and 4 is Al, the main material of the covering layer 40 is not Al. With this configuration, the article 100 can have abrasion resistance and weather resistance.

Silsesquioxane is a compound having a T3 unit structure represented by the compositional formula [R1(SiO1.5)n] (R1 is a functional group, and indicates at least one selected from the group consisting of a polymerizable group, a hydroxy group, a chlorine atom, alkyl groups with 1 to 6 carbon atoms, and alkoxy groups with 1 to 6 carbon atoms, for example) and is a hybrid material of silicon oxide and an organic substance.

Silsesquioxane (hereinafter sometimes abbreviated to SQ) is a siloxane compound with the main chain backbone composed of Si—O bond and is represented by the compositional formula [R1(SiO1.5)n]. At this time, R1 is preferably a polymerizable group, and R1 is more preferably at least one polymerizable group selected from the group consisting of an acryloyl group, a methacryloyl group, an oxetanyl group, and an epoxy group. With this configuration, it is possible to grant excellent abrasion resistance to the article 100.

In a case where silsesquioxane plays a role of binding a large number of particles including a solid material together, it becomes possible to realize more excellent strength while retaining high porosity. Silsesquioxane may have any polymer form. Examples of polymer forms include known linear polysiloxane, cage-like polysiloxane, and ladder-like polysiloxane. The silsesquioxane structure is a structure in which each silicon atom is bonded with three oxygen atoms and each oxygen atom is bonded with two silicon atoms (the number of oxygen atoms relative to the number of silicon atoms is 1.5). Linear polysiloxane, cage-like polysiloxane, and ladder-like polysiloxane may be mixed in terms of cost. A desirable thickness of a silsesquioxane layer is equal to or greater than 20 nm and equal to or less than 180 nm, and is preferably equal to or greater than 30 nm and equal to or less than 150 nm.

The silsesquioxane is preferably a compound with a polymerizable group (R1 in the above-described compositional formula) in the molecule and curable by radical polymerization or cationic polymerization. R1 is preferably at least one polymerizable group selected from the group consisting of an acryloyl group, a methacryloyl group, an oxetanyl group, and an epoxy group. Examples of silsesquioxane curable by radical polymerization include silsesquioxane with an acryloyl group or a methacryloyl group as R1.

In contrast, examples of silsesquioxane curable by cationic polymerization include silsesquioxane with an oxetanyl group or an epoxy group as R1. Specific examples include silsesquioxane derivatives SQ series (AC-SQ, MAC-SQ, and OX-SQ) manufactured by Toagosei Co., Ltd.

As described above, in addition to inclusion of the covering layer 40 made of an inorganic material (e.g., silsesquioxane layer), the article 100 of the present disclosure preferably further includes the covering layer 40 made of an organic material. Examples of materials used in the covering layer 40 made of an organic material include fluorine resin and acrylic resin. The covering layer 40 made of an organic material is preferably formed on the covering layer 40 made of the above-described inorganic material (e.g., silsesquioxane layer). With this configuration, it is possible to grant weather resistance to the article 100.

The covering layer 40 preferably includes a fluoroolefin copolymer (fluoroolefin polymer) as a fluorine resin. The fluoroolefin copolymer is a copolymer of fluoroolefin and another copolymerizable monomer copolymerizable with fluoroolefin.

Examples of fluoroolefin included in a fluoroolefin copolymer include fluoroolefin with 2 to 3 carbon atoms, such as tetrafluoroethylene, chlorofluoroethylene, hexafluoropropylene, vinylidene fluoride, and vinyl fluoride. A percentage of a polymerization unit that is based on fluoroolefin in a fluoroolefin copolymer is preferably 20 to 70 mole % to give sufficient weather resistance to a coating film. Another copolymerizable monomer included in a fluoroolefin copolymer is preferably a vinyl monomer, in other words, a compound having carbon-carbon double bond is preferable.

As vinyl monomers, for example, vinyl ether, allyl ether, carboxylic acid vinyl ester, carboxylic acid allyl ester, and olefin are exemplified. A known acrylic resin can be used.

The covering layer 40 may include acrylic resin. The acrylic resin is a resin containing a (meth)acrylic polymer. A content rate of a (meth)acrylic polymer in acrylic resin is normally equal to or greater than 30 mass %, preferably equal to or greater than 50 mass %, more preferably equal to or greater than 70 mass %, especially-preferably equal to or greater than 90 mass %, and most preferably equal to or greater than 95 mass %. The (meth)acrylic polymer has excellent optical characteristics such as high light transmittance and low wavelength dependency of a refractive index.

The (meth)acrylic polymer is a polymer having a constituent unit (a (meth)acrylic acid ester unit) derived from a (meth)acrylic acid ester monomer. Normally, a content rate of the (meth)acrylic acid ester unit in the (meth)acrylic polymer is preferably equal to or greater than 10 mass %, more preferably equal to or greater than 30 mass %, further preferably equal to or greater than 50 mass %, and especially preferably equal to or greater than 70 mass %.

The (meth)acrylic polymer may have a constituent unit other than the (meth)acrylic acid ester unit. Such a constituent unit is a constituent unit derived from each monomer of styrene, vinyltoluene, α-methylstyrene, α-hydroxymethylstyrene, α-hydroxyethylstyrene, acrylonitrile, methacrylonitrile, ethylene, propylene, 4-methyl-1-pentene, vinyl acetate, 2-hydroxymethyl-1-butene, methyl vinyl ketone, N-vinylpyrrolidone, and N-vinylcarbazole, for example. The (meth)acrylic polymer may have two or more types of these constituent units.

An organic material used in the covering layer 40 is not limited to a fluorine resin and an acrylic resin, and may be any material that has transparency and weather resistance.

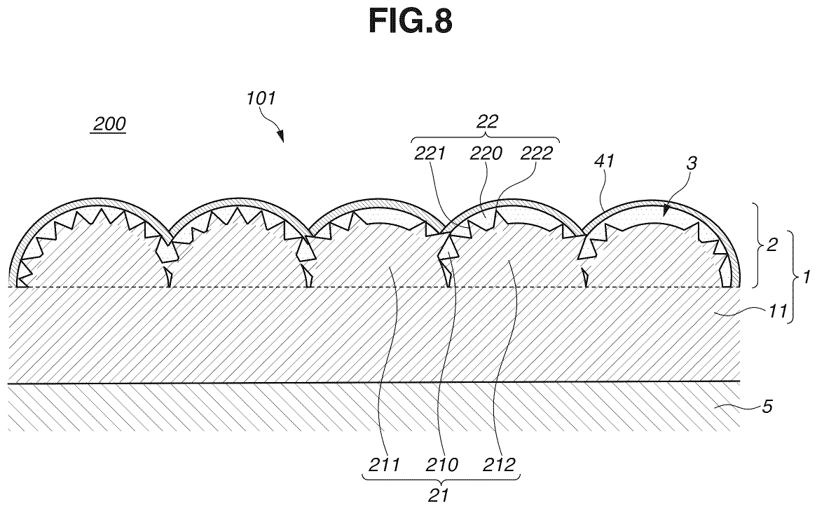

As illustrated in FIG. 8, the article 100 of the present disclosure preferably includes an ink layer 41 on the metal oxide layer 3. The ink layer 41 is preferably arranged on an outermost layer of the article 100. The ink layer 41 is able to control an emissivity of infrared light and a reflectance of visible light, and has a function of increasing a design property for coloring the article 100.

Although the ink layer 41 is laid in contact with the metal oxide layer 3 in FIG. 8, at least one of the metal oxide layer 4, the covering layer 40 made of an inorganic material, and the covering layer 40 made of an organic material may be arranged between the metal oxide layer 3 and the ink layer 41. The ink layer 41 may be disposed not via the metal oxide layer 3. The ink layer 41 is only required to be laid above the irregularity structure 2 in at least one of the regions 101, 102, 103, and 104.

The thickness of the ink layer 41 is preferably smaller than the arithmetic average roughness Ra of the first irregularity structure 21. This makes it easier to achieve a design property given by the ink layer 41, and a heat shield property of the first irregularity structure 21. The thickness of the ink layer 41 preferably falls within the range equal to or greater than 100 nm and equal to or less than 1 μm.

The ink layer 41 can be formed using various types of inkjet ink, such as water-based ink, solvent ink, and ultraviolet (UV) curable ink, and ink to be used in an embodiment is not limited. Among these types of ink, it is preferable to use UV curable ink. Hereinafter, each component contained in ink forming the ink layer 41 will be described in detail.

Ink includes a polymerizable compound, a photopolymerization initiator, a coloring agent, and a solvent, and can include other additive components.

### [Polymerizable Compound]

A polymerizable compound (A) contained in ink is a compound that reacts with a polymerizing factor (radical, etc.) generated from a photopolymerization initiator (B) to be described below, and becomes a hardened material formed from a high-molecular compound (polymer), by a chain reaction (polymerization reaction).

The polymerizable compound (A) includes a polymerizable functional group. In this specification, the polymerizable functional group refers to a functional group that is polymerizable. The polymerizable functional group included in the polymerizable compound (A) is preferably a polymerizable functional group that is radically polymerizable, and among such polymerizable functional groups, the polymerizable functional group is more preferably an ethylenically unsaturated group. Specifically, the polymerizable functional group included in the polymerizable compound (A) is especially preferably an acryloyl group, a methacryloyl group, a vinyl group, an allyl group, or a vinyl ether group.

The polymerizable compound (A) contained in ink may be one type of polymerizable compound, or may be a plurality of types of polymerizable compounds. In a case where a plurality of types of polymerizable compounds are contained, a mixture ratio in ink containing the polymerizable compounds is calculated based on the total of the mass of the plurality of types of polymerizable compounds in the embodiment.

The polymerizable compound (A) is not specifically limited as long as the polymerizable compound (A) is a compound including a polymerizable functional group, and a monomer, an oligomer, a polymer, a mixture of these, and the like are useable. In a case where a solid-state polymerizable compound is used, it is preferable to mix the solid-state polymerizable compound with a liquid-state polymerizable compound, and use the solid-state polymerizable compound with being dissolved in the liquid-state polymerizable compound.

When a total mass of ink is 100 mass %, a mixture ratio of the polymerizable compound (A) in ink is preferably equal to or greater than 30 mass % and equal to or less than 90 mass %. The mixture ratio is more preferably equal to or greater than 40 mass % and equal to or less than 80 mass %. A mixture ratio of the polymerizable compound (A) in ink is set to 30 mass % or more relative to a total mass of ink, so that it is possible to enhance mechanical strength of a hardened material to be formed.

### [Photopolymerization Initiator]

The photopolymerization initiator (B) contained in ink is a compound that senses light in a predetermined wavelength (active energy rays) and generates a polymerizing factor (radical, etc.). Specifically, the photopolymerization initiator is a polymerization initiator that generates a polymerizing factor by active energy rays such as light (infrared light, visible light rays, ultraviolet rays, far-ultraviolet rays, X-rays, charged particle beams such as electron beams, radiant rays, etc.). More specifically, the photopolymerization initiator (B) preferably contains a polymerization initiator that generates a polymerizing factor by light in a wavelength equal to or greater than 150 nm and equal to or less than 400 nm, for example.

The photopolymerization initiator contained in ink may be one type of photopolymerization initiator, or may be a plurality of types of photopolymerization initiators. In a case where a plurality of types of photopolymerization initiators are contained, a mixture ratio in ink containing the photopolymerization initiators is calculated based on the total of the mass of the plurality of types of photopolymerization initiators in the embodiment.

When a total mass of ink is 100 mass %, a mixture ratio of the photopolymerization initiator is preferably equal to or greater than 0.01 mass % and equal to or less than 15 mass %, and is more preferably equal to or greater than 0.1 mass % and equal to or less than 10 mass %.

A mixture ratio of the photopolymerization initiator is set to 0.01 mass % or more relative to a total mass of ink, so that a curing speed of ink increases, thus enhancing reaction efficiency. The mixture ratio is set to 15 mass % or less relative to the total mass of ink, so that mechanical strength of a hardened material to be formed is enhanced.

### [Coloring Agent]

Ink according to the present disclosure may contain a coloring agent for producing a desired reflectance. Examples of the coloring agent include known pigment and dye. Examples of the pigment include known pigments of carbon black, cyan, yellow, magenta, and the like.

### [Solvent]

Examples of the solvent contained in ink include an organic solvent, water, and the like. Specific examples of the solvent include water; alcohols such as ethanol, 2-propanol, and butanol; various aliphatic or alicyclic hydrocarbons such as n-hexane, n-octane, cyclohexane, and cyclopentane; various aromatic hydrocarbons such as toluene; various esters such as ethyl formate and ethyl acetate; various ketones such as acetone, methyl ethyl ketone, and methyl isobutyl ketone; various ethers such as dimethoxyethane, tetrahydrofuran, dioxane, and diisopropyl ether; various chlorinated hydrocarbons such as chloroform, methylene chloride, and carbon tetrachloride, but the solvent is not limited to these. These low boiling point solvents may be used alone or may be used in combination of two or more types.

The solvent is preferably a liquid that is compatible with the polymerizable compound (A) and the photopolymerization initiator (B). When a total mass of ink is 100 mass %, a mixture ratio of the solvent in ink is preferably equal to or greater than 10 mass % and equal to or less than 50 mass %, and more preferably equal to or greater than 10 mass % and equal to or less than 40 mass %

### [Other Additive Components]

Ink may further contain additive components depending on various purposes without impairing the effect of the present disclosure. Examples of such additive components include a surface acting agent and an electrically-conductive material. The ink containing a surface acting agent enhances the dispersion stability of a coloring agent dispersing in the ink. Inclusion of an electrically-conductive material enables control of electric conductivity, thermal conductivity, and a function of electromagnetic wave absorption of the article 100.

The surface acting agent may include one type of surface acting agent, or may include a plurality of types of surface acting agents.

Examples of the hydrocarbon series surface acting agent include polyoxyalkylene alkyl ether obtained by adding an alkylene oxide with 2 to 4 carbon atoms, to alkyl alcohol with 1 to 50 carbon atoms.

Examples of polyoxyalkylene alkyl ether include a methyl alcohol ethylene oxide adduct, a decyl alcohol ethylene oxide adduct, lauryl alcohol ethylene oxide adduct, a cetyl alcohol ethylene oxide adduct, an oleyl alcohol ethylene oxide adduct, a stearyl alcohol ethylene oxide adduct, and the like. In a case where ink contains a surface acting agent, a content of the surface acting agent is preferably equal to or greater than 0.001 mass % and equal to or less than 20 mass %, for example, relative to a total amount of the ink. The content is more preferably equal to or greater than 0.01 mass % and equal to or less than 10 mass %, and furthermore preferably equal to or greater than 0.1 mass % and equal to or less than 10 mass %. The content of the surface acting agent is set within the above-described range, so that the dispersion stability of a liquid droplet is enhanced.

The electrically-conductive material may include one type of electrically-conductive material, or may include a plurality of types of electrically-conductive materials.

Examples of the electrically-conductive material include a carbon nanotube, a carbon nanofiber, graphene, graphite, electrically-conductive carbon black, metal particles or metal fibers of gold, silver, nickel, aluminum, iron, and the like.

A unit of providing electric conductivity, thermal conductivity, and a function of electromagnetic wave absorption to the article 100 is not specifically limited. For example, it is possible to dispose a layer made of an electrically-conductive material or a layer including an electrically-conductive material, on a superficial layer of the article 100 without impairing the effect of the present disclosure. It is possible to dispose a layer made of an electrically-conductive material or a layer including an electrically-conductive material, on a rear surface of the article 100, or attach an electrically-conductive sheet thereto.

In the case of disposing, on the superficial layer of the article 100, a layer made of an electrically-conductive material or a layer including an electrically-conductive material, the thickness of the layer made of an electrically-conductive material preferably falls within the range equal to or greater than 100 nm and equal to or less than 1 μm. If the thickness falls within this range, it is possible to achieve all of an effect of controlling a reflectance of visible light, a function of reducing an emissivity of infrared light, and an electric conductivity function.

In the case of disposing, on the rear surface of the article 100, a layer made of an electrically-conductive material or a layer including an electrically-conductive material, the thickness of the article 100 preferably falls within the range equal to or greater than 100 nm and equal to or less than 5 μm. The thicknesses of a layer made of an electrically-conductive material or a layer including an electrically-conductive material, and an electrically-conductive sheet-like object preferably falls within the range equal to or greater than 50 μm and equal to or less than 5 mm. If the thicknesses fall within this range, it is possible to achieve all of an effect of controlling a reflectance of visible light, a function of reducing an emissivity of infrared light, and an electric conductivity function.

### [Physical Properties of Photocurable Ink]

The viscosity of ink at 25° C. is preferably equal to or greater than 1 mPa·s and equal to or less than 75 mPa·s. The viscosity of ink is more preferably equal to or greater than 1 mPa·s and equal to or less than 30 mPa·s. The viscosity of ink is set to 1 mPa·s or more and 75 mPa·s or less, so that ejection stability in ejecting ink by an inkjet method is enhanced.

### [Preparation Method for Photocurable Ink]

A method of preparing ink is not specifically limited, but an example of a preparation method of ink will be described below. Ink is prepared by stirring and mixing the polymerizable compound (A), the photopolymerization initiator (B), and the coloring agent and making preparation.

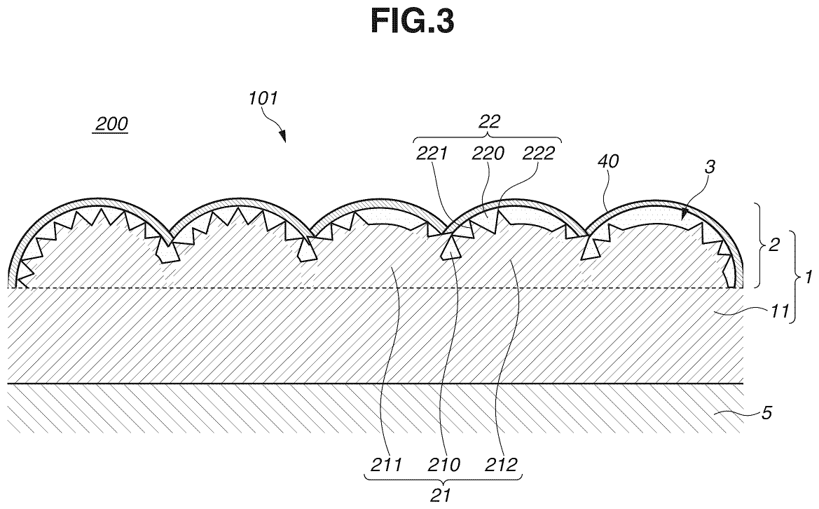

In stirring and mixing, a homogenizer, an ultrasonic disperser, a stirrer, or the like can be used. Among these, from the viewpoint of preparing a homogeneous ink, it is preferable to use a homogenizer or an ultrasonic disperser. As illustrated in FIG. 3, a member 200 according to an embodiment of the present disclosure is the member 200 in which a base material 5 is disposed on the surface of the metal layer 1 of the article 100 according to the present embodiment that is on the opposite side of the irregularity structure 2. The member 200 includes the base material 5, and the article 100 disposed on the base material 5. The shape of the base material 5 is only required to be a shape that can be made into a shape suitable for the intended purpose. For example, the base material 5 may be a molded article. Examples of shapes include a plate shape, a film shape, a sheet shape, and the like, but the shape is not limited to these.

Examples of materials of the base material 5 include metal, glass, ceramics, wood, paper, resin, and the like, but the material is not limited to these. Examples of the resin include thermoplastic resin such as polyester, triacetyl cellulose, cellulose acetate, polyethylene terephthalate, polypropylene, polystyrene, polycarbonate, and polymethyl methacrylate. Alternatively, acrylonitrile butadiene styrene (ABS) resin, polyphenylene oxide, polyurethane, polyethylene, polyvinyl chloride, and the like are also included in the examples of thermoplastic resins. The examples further include thermosetting resin such as unsaturated polyester resin, phenol resin, crosslinked polyurethane, crosslinked acrylic resin, crosslinked saturated polyester resin, and the like.

The article 100 and the base material 5 may be bonded by a bonding layer. A bonding layer included in the member 200 may be any layer as long as the layer can bond the article 100 and the base material 5. Examples of the bonding layer include a layer made of a hardened material of an adhesive resin (e.g., epoxy resin, etc.), a double-stick tape, and the like.

An article according to the present embodiment includes the article 100. The article 100 according to the present embodiment can be disposed on the surfaces of various members or articles. The article 100 according to the present embodiment is preferably used in a heat generator including a heat generation unit serving as a member or an article. Examples of an article including such a heat generator include a battery, an engine, a motor, a vehicle, and the like. The engine is a reciprocating engine, a rotary engine, a diesel engine, a gas turbine engine, a jet engine, a rocket engine, or the like. The motor is a direct-current (DC) motor, an alternating-current (AC) motor, a permanent magnet (PM) motor, a brush motor, a stepping motor, an induction motor, a servo motor, an ultrasonic motor, an in-wheel motor, a linear motor, or the like. A transport device including at least one of an engine and a motor may include the article 100. The transport device including at least one of an engine and a motor is not limited to various vehicles such as an automobile and an electric train, and includes a ship and a vessel, an aircraft such as a drone, and various robots such as an automated guided vehicle (AGV). The transport device is not limited to a transport device for passenger transport, and may be a transport device for cargo transport, or may be a driverless transport device operated by remote control or autonomous guidance. A hybrid automobile is a vehicle including a battery, an engine, and a motor. The article 100 and the member 200 according to the present embodiment can be used as a member for preventing stray light in an optical device, and a heat shielding member, or as an interior or exterior member of a space-related device such as an artificial satellite, and can also be used as an exterior film, a solar collector, or the like. Aside from these, the article 100 according to the present embodiment can also be used in clothes or the like. The article 100 according to the present embodiment may be used as a decorative film for heat shielding. For example, as a decorative film for heat shielding, the article 100 according to the present embodiment can also be fixed to the surfaces of the interior and exterior of a vehicle, a mobile device, a home electric appliance, a parasol, and tent goods. When the article 100 according to the present embodiment is disposed on the surface of a member or an article, various adhesive agents can be used. Thus, the article 100 according to the present embodiment can be disposed on the surface of a member or an article depending on the intended purpose, and the surface of the member or the article is not limited to a smooth surface, and may be a two-dimensional or three-dimensional curved surface.

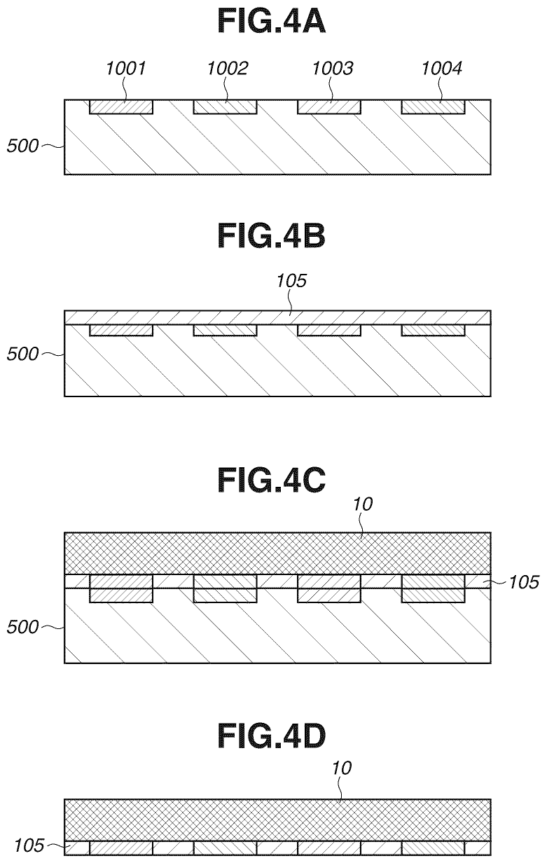

Next, a manufacturing method of the article 100 according to the present embodiment will be described with reference to FIGS. 4A to 4D. As a method of forming a plurality of regions 101 to 104 different in emissivity of infrared light of the article 100, there is a method of forming the regions by applying a coloring agent for optical camouflage onto a sheet on which an emissivity of infrared light is uniformly controlled, for example. As the coloring agent for optical camouflage, pigment and/or dye for camouflage is/are useable. As the coloring agent for optical camouflage, for example, pigments of green, brown, gray, and black that have hues harmonized with a natural environment or an artificial environment are preferably used. The coloring agent for optical camouflage is applied onto the surface of a sheet on which an emissivity is uniformly controlled, using a method such as inkjet, coating, spraying, or printing that uses sublimation transfer or electrolyzation. In addition to the method, a method of forming a plurality of regions 101 to 104 different in emissivity of infrared light of the article 100 may be a method of forming regions different in roughness on a base substrate surface.

A manufacturing method to be described below is an example, and any manufacturing method with which a plurality of regions 101 to 104 different in emissivity of infrared light of the article 100 are formable is applicable.

### (Process of Forming Metal Oxide Layer 3)

Initially, a base substrate 500 is prepared. The base substrate 500 is only required to be a base material having been subjected to mirror polishing, or a base substrate having a micro-order irregularity structure on a base material surface. Examples of the base substrate 500 include obscure glass roughened by a polishing agent or etching liquid such as acid or alkali or a base material processed by electron beams, but the base substrate 500 is not limited to these. By forming a micro-order structure on a film applied on a surface, a base material may be prepared.

After that, regions 1001 to 1004 corresponding to the regions 101 to 104 of the article 100 are formed as illustrated in FIG. 4A. The regions 1001 to 1004 are regions different in roughness, and are regions rougher than the surface of the base substrate 500. A sandblasting method is preferably used as a formation method of the regions 1001 to 1004. As the roughness of each region, an average roughness Ra is preferably equal to or greater than 0.1 μm and equal to or less than 5 μm.

Subsequently, as illustrated in FIG. 4B, a film 105 containing aluminum is formed on the surface of the base substrate 500 on which the regions 1001 to 1004 are formed. Thus, an irregularity structure reflecting the roughnesses of the regions 1001 to 1004 is formed on the surface of the film 105. The irregularity structure of the film 105 includes a plurality of recess portions, and a plurality of protruding portions between the plurality of recess portions. The plurality of recess portions of the film 105 reflects a plurality of recess portions of the base substrate 500, and the plurality of protruding portions of the film 105 reflects a plurality of protruding portions of the base substrate 500. After that, by the film 105 transubstantiating, a metal oxide layer disposed with an irregularity structure can be formed on the base substrate 500.

The material of the metal oxide layer is not specifically limited, but the metal oxide layer preferably contains aluminum oxide as a main component. The irregularity structure is formable with a known vapor deposition method such as chemical vapor deposition (CVD) or physical vapor deposition (PVD), and a liquid phase method such as sol-gel method. With these methods, it is possible to provide an irregularity structure of a metal oxide including a plate crystal containing aluminum oxide as a main component. Among these methods, a method of processing a film containing aluminum, using hot water, and glowing aluminum oxide plate crystal is preferable.

Examples of the film containing aluminum include aluminum oxide gel film formed by applying sol-gel coating liquid containing an aluminum compound, a film containing metal aluminum that has been formed by dry film formation such as vacuum deposition or sputtering method, and the like. From the viewpoint of reactivity and easy adjustment of the height of an irregularity structure of a metal oxide, it is preferable to form an irregularity structure of a metal oxide using aluminum oxide gel film.

As the raw material of the aluminum oxide gel film, an aluminum compound such as an aluminum alkoxide, an aluminum halide, and aluminum salt are useable. From the viewpoint of a film formability, an aluminum alkoxide is preferably used.

Examples of the aluminum compound include an aluminum alkoxide such as aluminum ethoxide, an aluminum isopropoxide, an aluminum-n-butoxide, an aluminum-sec-butoxide, and an aluminum-tert-butoxide. Examples further include an oligomer of these, an aluminum halide such as aluminum chloride, aluminum salt such as aluminum nitrate, aluminum acetate, aluminum phosphate, and aluminum sulfate, aluminum acetylacetonate, aluminum hydroxide, and the like.

The aluminum oxide gel film may contain other compounds. Examples of the other compounds include zirconium, silicon, titanium, a zinc alkoxide, a halide, salt, and a combination of these. By the aluminum oxide gel film containing the other compounds, as compared with a case where these are not contained, it is possible to increase the height of an irregularity structure of a metal oxide to be formed.

As described below, the aluminum oxide gel film is formed onto the base substrate 500 by applying sol-gel coating liquid containing an aluminum compound. The sol-gel coating liquid is prepared by dissolving an aluminum compound in an organic solvent. An amount of the organic solvent relative to the aluminum compound is preferably about 20 times in terms of molar ratio.

As the organic solvent, alcohol, carboxylic acid, aliphatic hydrocarbon, alicyclic hydrocarbon, aromatic hydrocarbon, ester, ketone, ether, or a mixed solvent of these can be used. Examples of the alcohol include methanol, ethanol, 2-propanol, butanol, 2-methoxyethanol, 2-ethoxyethanol, 1-methoxy-2-propanol, 1-ethoxy-2-propanol, and the like. The examples further include 1-propoxy-2-propanol, 4-methyl-2-pentanol, 2-ethylbutanol, 3-methoxy-3-methylbutanol, ethylene glycol, diethylene glycol, glycerin, and the like. Examples of the carboxylic acid include n-butyric acid, α-methylbutyric acid, iso-valeric acid, 2-ethylbutyric acid, 2,2-dimethylbutyric acid, 3,3-dimethylbutyric acid, 2,3-dimethylbutyric acid, 3-methylpentanoic acid, 4-methylpentanoic acid, and the like. The examples further include 2-ethylpentanoic acid, 3-ethylpentanoic acid, 2,2-dimethylpentanoic acid, 3,3-dimethylpentanoic acid, 2,3-dimethylpentanoic acid, 2-ethylhexanoic acid, 3-ethylhexanoic acid, and the like. Examples of aliphatic hydrocarbon or alicyclic hydrocarbon include n-hexane, n-octane, cyclohexane, cyclopentane, cyclooctane, and the like. Examples of aromatic hydrocarbon include toluene, xylene, ethylbenzene, and the like. Examples of the esters include ethyl formate, ethyl acetate, n-butyl acetate, ethylene glycol monomethyl ether acetate, ethylene glycol monoethyl ether acetate, ethylene glycol monobutyl ether acetate, and the like. Examples of ketones include acetone, methyl ethyl ketone, methyl isobutyl ketone, cyclohexanone, and the like. Examples of ethers include dimethoxyethane, tetrahydrofuran, dioxane, diisopropyl ether, and the like. Among these, from the viewpoint of stability of sol-gel coating liquid, it is preferable to use alcohol.

In a case where an aluminum alkoxide is used as an aluminum compound, because reactivity to water is high, the aluminum alkoxide is rapidly hydrolyzed due to the addition of moisture in air or water, and white turbidity and sedimentation of the sol-gel coating liquid sometimes occur. To prevent these, it is preferable to achieve stabilization by adding a stabilizer to the sol-gel coating liquid. As the stabilizer, β-diketone compounds, B-ketoester compounds, alkanolamines, and the like can be used. Examples of the B-diketone compounds include acetylacetone, trifluoroacetylacetone, hexafluoroacetylacetone, benzoylacetone, 3-methyl-2,4-pentanedione, 3-ethyl-2,4-pentanedione, and the like. Examples of the β-ketoester compounds include methyl acetoacetate, ethyl acetoacetate, butyl acetoacetate, hexyl acetoacetate, allyl acetoacetate, benzyl acetoacetate, iso-propyl acetoacetate, and the like. The examples further include 2-methoxyethyl acetoacetate, sec-butyl acetoacetate, tert-butyl acetoacetate, iso-butyl acetoacetate, and the like. Examples of alkanolamines include monoethanolamine, diethanolamine, triethanolamine, and the like. The amount of stabilizer relative to the aluminum alkoxide is preferably about 1 time in terms of molar ratio.

To promote a hydrolysis reaction of an aluminum alkoxide, a catalyst may be used. Examples of the catalyst include nitric acid, hydrochloric acid, sulfuric acid, phosphoric acid, acetic acid, ammonia, and the like.

A water-soluble organic polymer compound is addable to the aluminum oxide gel film as necessary. The water-soluble organic polymer compound is easily eluted from the aluminum oxide gel film by immersion in hot water, a reaction surface area of an aluminum compound and hot water accordingly increases, and this enables the formation of an irregularity structure at low temperatures and in a short time. Changing the type and the molecular weight of an organic polymer to be added enables control of the height of an irregularity structure to be formed. As the organic polymer, polyether glycols such as polyethylene glycol and polypropylene glycol are preferable because these are easily eluted from the aluminum oxide gel film by immersion in hot water. The amount of polyether glycols relative to the weight of the aluminum compound in the aluminum oxide gel film preferably falls within the range from 0.1 times to 10 times in terms of weight ratio.

### (Process of Forming Metal Layer 1)

A metal layer 10 is formed on the film 105 containing aluminum on which an irregularity structure is formed, so that the metal layer 10 having an irregularity structure onto which an irregularity structure has been transferred is formed. A process of forming the metal layer 10 on the film 105 will be described below with reference to FIG. 4C. As a formation method of the metal layer 10, metal plating processing is preferable, and electroless plating processing is further preferable. In the electroless plating processing, activation is performed by applying aqueous solution containing a palladium compound such as palladium chloride, a gold compound such as gold chloride, a silver compound such as silver chloride, a tin compound such as tin chloride, and/or the like that are/is dissolved therein, to the film 105 on which the irregularity structure is formed. The activation may be performed by immersing the irregularity structure in aqueous solution in which a palladium compound is dissolved, together with a base material. After that, using electroless plating solution, the metal layer 10 is deposited on the film 105 on which an irregularity structure is formed. The metal layer 10 corresponds to the metal layer 1 of the article 100 according to the present embodiment, and electroless plating solution containing a nickel ion, a chrome ion, or a zinc ion is preferable, and nickel plating solution containing a nickel ion is especially preferable. In addition to a nickel component, the nickel plating solution may contain a phosphorous component or a boron component. Examples of commercially available nickel plating solution include TOP NICORON series manufactured by OKUNO Chemical Industries Co., Ltd. The temperature of plating solution in the electroless plating processing is preferably equal to or greater than 30° C. and equal to or less than 98° C., and further preferably equal to or greater than 50° C. and equal to or less than 90° C. A time for which the electroless plating processing is to be performed can be adjusted in accordance with the thickness of the metal layer 10 to be formed. Normally, the time is from 30 seconds to an hour. In this manner, the metal layer 10 is formed in such a manner as to bury clearance gaps in the irregularity structure on the film 105, and the metal layer 10 including an irregularity structure onto which the irregularity structure on the film 105 is transferred is formed. At this time, a portion positioned superior to a summit of a protruding portion of the irregularity structure corresponds to the base portion 11, and a portion positioned inferior to the summit of the protruding portion of the irregularity structure corresponds to the irregularity structure 2. That is, the metal layer 1 including the base portion 11, the first irregularity structure 21, and the second irregularity structure 22 is formed. The metal layer 1 is preferably a plated layer. Main components of metal materials of the metal layer 1 including the base portion 11, the first irregularity structure 21, and the second irregularity structure 22 are preferably the same.

The electroless plating processing is preferably performed in such a manner that the thickness of the metal layer 10 including the irregularity structure is equal to or greater than 200 nm and equal to or less than 15000 nm. The metal layer 10 is formed in such a manner as to cover the summit of the protruding portion of the irregularity structure, and because the portion corresponds to the base portion 11, the thickness of the base portion 11 can be equal to or greater than 200 nm and equal to or less than 15000 nm. An average height of the second irregularity structure 22 in the irregularity structure corresponds to an average height of the irregularity structure of the film 105, and becomes equal to or greater than 100 nm and equal to or less than 1000 nm. If the thickness of the metal layer 10 including the irregularity structure is equal to or greater than 200 nm, the article 100 according to the present embodiment exhibits excellent light absorption and heat shielding properties.

After the above-described electroless plating processing has been performed, to increase the thickness of the metal layer 10, electroplating processing may be performed on a surface of the metal layer 10 that is opposite to the surface on which the irregularity structure is disposed. Known electroplating solutions are useable in the electroplating processing. For example, electroplating solution containing a nickel ion, an iron ion, a copper ion, or the like as a metal ion can be used. In a case where the electroplating processing is performed using the same metal as the metal of the metal layer 10, it is possible to increase the thickness of the metal layer 10 by the electroplating processing. In a case where electroplating processing is performed on the metal layer 10 using metal different from the metal of the metal layer 10, the metal layer 10 disposed by the electroplating processing becomes a base material. In addition to inorganic salts serving as raw materials of metal ions, electrically-conductive salts, salts for adjusting counter ions, carboxylic acid additives for improving the homogeneity of the plating film, a brightening agent, and the like may be added to the electroplating solution as necessary. In an electroplating process, by adjusting a liquid temperature of electroplating solution, current density, and a plating time, the thickness of the metal layer 10 can be set to a desired thickness. As necessary, activation processing of the surface of the metal layer 10 that is opposite to the surface on which the irregularity structure is disposed may be performed before the electroplating process using aqueous solution containing acid or the like. Furthermore, to improve the quality of a film to be formed by the electroplating processing, in addition to stirring the electroplating solution during the electroplating processing, a process of removing a foreign object in the electroplating solution may be included.

### (Etching Process)

Next, to obtain the article 100, the removal of the base substrate 500 is performed. FIG. 4D illustrates a state obtainable after the etching of the base substrate 500. The film 105 containing aluminum is disposed on the surface of the metal layer 10. In a case where the film 105 is a film containing metal aluminum, because visible light is reflected by the metal aluminum, the film containing metal aluminum is to be further removed by etching. In the case of a metal oxide layer (a layer containing amorphous gel of aluminum oxide), the layer containing amorphous gel of aluminum oxide is a metal oxide layer of a light absorption and heat shielding member. Thus, the layer containing amorphous gel of aluminum oxide may be removed by etching in such a manner as to satisfy required surface hardness and light absorption property. As an etching method, wet etching that dissolves a film containing metal aluminum or a metal oxide layer using acid or alkali solution is preferable. Examples of acid include hydrochloric acid, nitric acid, sulfuric acid, and the like. Examples of alkali include sodium hydroxide, potassium hydroxide, and the like.

From the viewpoint of work efficiency, an etching method that uses alkali solution is more preferable. It is preferable to perform etching with an etching concentration within the range from several percents to several tens of percents, and an etching time within the range from several hours to several days. The metal layer 10 in which a metal oxide adheres to the irregularity structure also has a great light absorption property, and is also able to enhance the strength of the irregularity structure, so that excellent durability and environment resistance are obtained.

A residual metal oxide such as aluminum oxide that remains after etching (metal oxide adhering to the irregularity structure 2) is detectable by the measurement that uses the EDX or the XPS during surface or cross-section observation that uses an SEM or a TEM.

As described above, it is sufficient that the degree of etching processing is adjusted in accordance with balance between desired light absorption performance and surface hardness of the article 100. Surface processing intended to increase mechanical strength may be performed on the outermost surface of the article 100 as appropriate. Examples of a surface processing agent include silsesquioxane and a fluorine resin.

The article 100 according to the present embodiment is preferably used in a heat generator serving as a member or a structural body. Examples of an article including such a heat generator include a battery, an engine, a motor, a vehicle, and the like. The engine is a reciprocating engine, a rotary engine, a diesel engine, a gas turbine engine, a jet engine, a rocket engine, or the like. The motor is a DC motor, an AC motor, a PM motor, a brush motor, a stepping motor, an induction motor, a servo motor, an ultrasonic motor, an in-wheel motor, a linear motor, or the like. A transport device including at least one of an engine and a motor may include an infrared emission amount control member. A transport device including at least one of an engine and a motor is not limited to various vehicles such as an automobile and an electric train, and includes a ship and a vessel, an aircraft such as a drone, and various robots such as an AGV. The transport device is not limited to a transport device for passenger transport, and may be a transport device for cargo transport, or may be a driverless transport device operated by remote control or autonomous guidance. A hybrid automobile is a vehicle including a battery, an engine, and a motor. The article 100 and the member 200 according to the present embodiment can be used as a member for preventing stray light in an optical device, and a heat shielding member, or as an interior or exterior member of a space-related device such as an artificial satellite, and can also be used as an exterior film, a solar collector, or the like.

Aside from these, the infrared emission amount control member according to the present embodiment is also useable in clothes or the like.

The infrared emission amount control member according to the present embodiment may be used as a decorative film for heat shielding. For example, as a decorative film for heat shielding, the infrared emission amount control member according to the present embodiment can also be fixed to the surfaces of the interior of a vehicle, a mobile device, a home electric appliance, a parasol, and tent goods. When the infrared emission amount control member according to the present embodiment is disposed on the surface of a member or an article, various adhesive agents can be used.

Thus, the infrared emission amount control member according to the present embodiment is disposable on the surface of a member or an article depending on the intended purpose, and the surface of the member or the article is not limited to a smooth surface, and may be a two-dimensional or three-dimensional curved surface.

In a case where thermal camouflage and optical camouflage effects dramatically degrade due to extreme usage environment, because the infrared emission amount control member of the present disclosure has a sheet shape, the infrared emission amount control member can be easily replaced by peeling the sheet.

### EXAMPLES

Hereinafter, examples of the present disclosure will be described. Nevertheless, the present disclosure is not limited to examples to be described below.

The evaluation of an infrared light emissivity in an example was performed by reflectance spectrum measurement of an infrared light region. A Fourier transform infrared spectrophotometer (manufactured by JASCO Corporation, FT/IR-6600) was used as a measurement apparatus. Using relational expressions of an energy conservation law and Kirchhoff's laws, an emissivity of the present disclosure was calculated from a reflectance. Because a transmittance of the present disclosure is about 0%, an emissivity % becomes a value obtained by subtracting a reflectance % from 100%.

The evaluation of a visible light reflectance in an example was performed by reflectance spectrum measurement of a visible light ray region. As a measurement apparatus, a lens reflectance measurement device (product name: USPM-RU III, manufactured by Olympus Corporation) was used.

### Example 1

### (Preparation of Base Substrate 500)

Ellipse regions 101 to 104 different in roughness were formed with the sandblasting method on the surface of the base substrate 500 made of quartz glass. The ellipse regions 101 to 104 each has different roughness.

A difference in roughness is attributed to a difference in type of sand to be used, and is conventionally represented by a number called a count number. For example, 1000th is represented as #1000. In this example, count numbers #800, #600, #400, and #220 were used for the roughnesses of the regions 101 to 104.

### (Preparation of Article 100 and Member 200)

Aluminum oxide sol solution was prepared by dissolving aluminum-sec-butoxide (hereinafter, will also be referred to as “Al(O-sec-Bu)₃”) and ethyl acetoacetate (hereinafter, will also be referred to as “EtOAcAc”) in 2-propanol (hereinafter, will also be referred to as “IPA”) and stirring these at room temperature for about three hours. The molar ratio of the components in the aluminum oxide sol solution was Al(O-sec-Bu)₃:EtOAcAc:IPA=1:1:20. Sol-gel coating liquid was prepared by adding 0.01M dilute hydrochloric acid aqueous solution to the aluminum oxide sol solution in such a manner that an added amount of the hydrochloric acid becomes twice relative to Al(O-sec-Bu)₃ in terms of molar ratio, and refluxing the mixture for about six hours. A coating film was formed by applying the sol-gel coating liquid using a spin coating method onto the base substrate 500 with the surface on which the ellipse regions 101 to 104 were formed by the sandblasting method. After that, a transparent aluminum oxide gel film was obtained by performing thermal treatment of the coating film at 100° C. for an hour. Next, by immersing the aluminum oxide gel film into hot water at 80° C. for 30 minutes and then drying the aluminum oxide gel film at 100° C. for 10 minutes, aluminum oxide layer having an irregularity structure was formed.

After palladium chloride aqueous solution was applied by the spin coating method onto the aluminum oxide layer having the irregularity structure, the aluminum oxide layer was dried at 100° C. After that, by immersing the aluminum oxide layer for 20 minutes in nickel-phosphorus plating solution (phosphorous content of about 1 to 2 wt %) set at 80° C., a nickel layer serving as the metal layer 1 including an irregularity structure and the base portion 11 below the irregularity structure was formed. After that, by peeling the article 100 from the quartz glass substrate, and performing etching processing at room temperature for 50 hours using 3M sodium hydroxide aqueous solution as an etching process, the article 100 was manufactured. The overall thickness of the obtained article 100 was about 10 μm.

### Example 2

By mixing and stirring predetermined amounts of the polymerizable compound (A), the photopolymerization initiator (B), a solvent, and a coloring agent, UV ink was prepared.

UV curable ink was dropped as droplets onto a polyethylene terephthalate (PET) film (manufactured by Teijin Dupont films, Tetron HL92W) using a micropipette. Furthermore, the PET film was covered with the article obtained in Example 1, and a covered area was filled with ink.

Next, light emitted from a UV light source including an ultrahigh pressure mercury lamp was emitted for 20 seconds through a diffuser panel and through the PET film. The ink sandwiched between the PET film and the article obtained in Example 1 was accordingly hardened. UV light with a wavelength of 365 nm and illuminance of 15 mW/cm² was used as irradiation light.

After the light illumination, by peeling the PET film and then leaving the PET film at room temperature (25° C.), an ink layer was formed on the article obtained in Example 1.

### (Optical Characteristic)

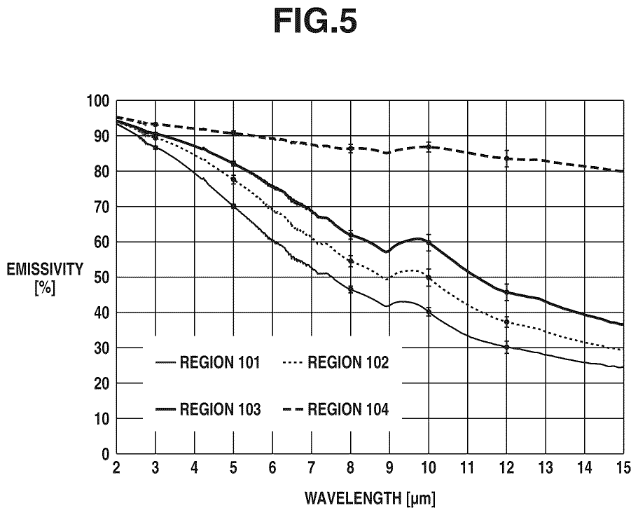

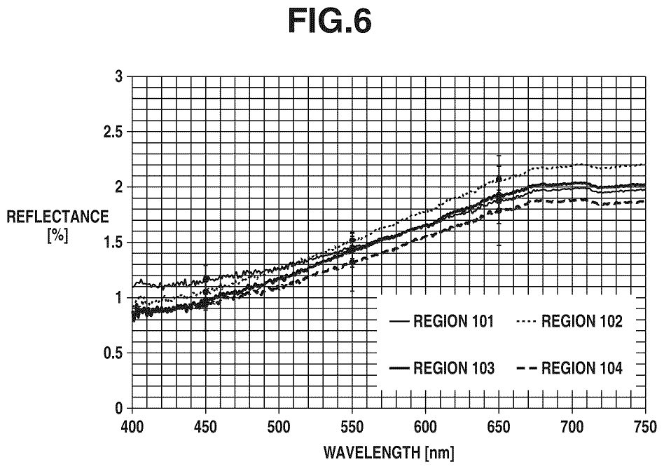

FIG. 5 illustrates a result of an emissivity spectrum measurement of infrared light in the regions 101 to 104, and FIG. 6 illustrates a result of a reflectance spectrum measurement of visible light in the regions 101 to 104.

As illustrated in FIG. 5, it can be seen that, when a wavelength is equal to or greater than 6 μm, an emissivity of infrared light of the article 100 is equal to or less than 90%, and when a wavelength is equal to or greater than 6 μm, a difference in emissivity between the regions is equal to or greater than 5%.

As illustrated in FIG. 6, it can be seen that, when a wavelength is equal to or greater than 400 nm and equal to or less than 750 nm, a reflectance of visible light of the article 100 is equal to or less than 10%, and when a wavelength is equal to or greater than 400 nm and equal to or less than 750 nm, a difference in reflectance between the regions is equal to or less than 5%.

When a wavelength was equal to or greater than 6 μm, an emissivity of infrared light of an article on which an ink layer was formed was equal to or less than 90%, and when a wavelength was equal to or greater than 6 μm, a difference in emissivity between the regions was equal to or greater than 5%.

When a wavelength was equal to or greater than 400 nm and equal to or less than 750 nm, a reflectance of visible light of an article on which an ink layer was formed was equal to or less than 10%, and when a wavelength was equal to or greater than 400 nm and equal to or less than 750 nm, a difference in reflectance between the regions was equal to or less than 5%.

### (Visibilities of Infrared Light and Visible Light Ray Provided by Article 100)

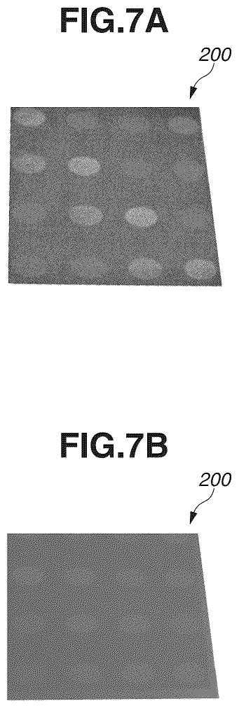

FIG. 7A illustrates an image of the member 200 (FIG. 3) of the present disclosure placed on a heater set at 40° C. that was captured by an infrared thermography apparatus (model type: H2640, manufactured by Nippon Avionics Co., Ltd.). As an image capturing environment, the temperature was room temperature and a distance between the member 200 and the measurement apparatus was about 40 cm. Since infrared light emissivities of neighboring regions are different, a difference in black and white contrasting density clearly appears, and it can be seen that an infrared camouflage effect is produced as the entire sheet member.

FIG. 7B illustrates an image obtained by visually checking (by visible light) the member 200 of the present disclosure in a dark room, and the pattern of this member was harmonized with an ambient environment, and it was difficult to visually identify the pattern.

The embodiment described above can be appropriately changed without departing from the technical idea. For example, a plurality of embodiments can be combined. A partial description in at least one embodiment can be deleted or replaced.

A new item can be added to at least one embodiment. The disclosure in this specification is not limited to the matters explicitly described in this specification, and includes all matters that can be identified from this specification and the drawings accompanying this specification.

The disclosure in this specification includes a complementary set of individual concepts described in this specification. More specifically, if “A is larger than B” is described in this specification, for example, even if the description “A is not larger than B” is omitted, this specification is assumed to disclose that “B is not larger than A”. This is because, in a case where “A is larger than B” is described, a case where “A is not larger than B” is assumed to be considered.

A technique advantageous in reducing an emissivity of infrared light while suppressing a reflectance of visible light is disposed.

While the present disclosure has been described with reference to embodiments, it is to be understood that the disclosure is not limited to the disclosed embodiments. The scope of the following claims is to be accorded the broadest interpretation so as to encompass all such modifications and equivalent structures and functions.

This application claims the benefit of priority from Japanese Patent Applications No. 2023-068096, filed Apr. 18, 2023, and No. 2024-004627, filed Jan. 16, 2024, which are hereby incorporated by reference herein in their entireties.

What is claimed is:

1. An article comprising:
a first region; and,
a second region disposed from the first region within a distance equal to or less than a width of the first region,
wherein an emissivity of infrared light in a first wavelength in the first region and the second region is equal to or less than 90%,
wherein a reflectance of visible light in a second wavelength in the first region and the second region is equal to or less than 10%, and
wherein a difference between an average emissivity (%) of infrared light in a wavelength equal to or greater than 8 μm and equal to or less than 13 μm in the first region, and an average emissivity (%) of infrared light in a wavelength equal to or greater than 8 μm and equal to or less than 13 μm in the second region is equal to or greater than 5%.

2. The article according to claim 1, wherein a difference between the reflectance of the visible light in the second wavelength in the first region and the reflectance of the visible light in the second wavelength in the second region is equal to or less than 10%.

3. The article according to claim 1, wherein a difference between an average emissivity (%) of visible light in a wavelength equal to or greater than 450 nm and equal to or less than 650 nm in the first region, and an average emissivity (%) of visible light in a wavelength equal to or greater than 450 nm and equal to or less than 650 nm in the second region is equal to or greater than 5%.

4. The article according to claim 1, wherein the first wavelength is equal to or greater than 6 μm.

5. The article according to claim 1, wherein the second wavelength is equal to or greater than 400 nm and equal to or less than 750 nm.

6. The article according to claim 1, wherein shapes of the first region and the second region are different from each other.

7. The article according to claim 1, wherein a difference between the emissivity (%) of the infrared light in the first wavelength in the first region and the emissivity (%) of the infrared light in the first wavelength in the second region is equal to or greater than 10%.

8. The article according to claim 1, wherein a difference between the emissivity (%) of the infrared light in the first wavelength in the first region and the emissivity (%) of the infrared light in the first wavelength in the second region is equal to or less than 50%.

9. The article according to claim 1, wherein an area of the first region and the second region is equal to or greater than 25 cm² and equal to or less than 10000 cm².

10. The article according to claim 1, further comprising a third region disposed from the second region within a distance equal to or less than a width of the second region, wherein a difference between the average emissivity (%) of the infrared light in the wavelength equal to or greater than 8 μm and equal to or less than 13 μm in the second region, and an average emissivity (%) of infrared light in a wavelength equal to or greater than 8 μm and equal to or less than 13 μm in the third region is equal to or greater than 5%.

11. The article according to claim 10, further comprising a fourth region disposed from the third region within a width of the third region,
wherein a difference between the average emissivity (%) of infrared light in the wavelength equal to or greater than 8 μm and equal to or less than 13 μm in the third region, and an average emissivity (%) of infrared light in a wavelength equal to or greater than 8 μm and equal to or less than 13 μm in the fourth region is equal to or greater than 5%.

12. The article according to claim 1, wherein an arithmetic average roughness Ra of the first region differs from an arithmetic average roughness Ra of the second region.

13. The article according to claim 1,
wherein the first region has a first irregularity structure and has, on a surface of the first irregularity structure, a second irregularity structure with an arithmetic average roughness Ra less than that of the first irregularity structure,
wherein the second region has a third irregularity structure and has, on a surface of the third irregularity structure, a fourth irregularity structure having an arithmetic average roughness Ra less than that of the third irregularity structure, and
wherein the arithmetic average roughness Ra of the first irregularity structure and the arithmetic average roughness Ra of the third irregularity structure are different, and/or the arithmetic average roughnesses Ra of the second irregularity structure and the fourth irregularity structure are different.

14. The article according to claim 13, wherein the arithmetic average roughnesses Ra of the first irregularity structure and the third irregularity structure are equal to or greater than 0.1 μm and equal to or less than 5 μm.

15. The article according to claim 13, wherein the arithmetic average roughnesses Ra of the second irregularity structure and the fourth irregularity structure are equal to or greater than 1 nm and equal to or less than 50 nm.

16. The article according to claim 13, wherein the article includes an ink layer above the first region and the second region.

17. The article according to claim 16, wherein a thickness of the ink layer is less than the arithmetic average roughness Ra of the first irregularity structure and the arithmetic average roughness Ra of the third irregularity structure.

18. The article according to claim 13, wherein the first irregularity structure, the second irregularity structure, the third irregularity structure, and the fourth irregularity structure are formed on a surface of a metal layer containing metal.

19. The article according to claim 18, further comprising a metal oxide layer covering the metal layer.

20. A structural body comprising:
a heat generator; and
the article according to claim 1,
wherein the article shields heat of the heat generator.
